(19) United States
(12) Patent Application Publication
(10) Pub. No.: US 2006/0237824 A1
(43) Pub. Date: Oct. 26, 2006

(54) Lead frame for semiconductor package and method of manufacturing the same

(75) Inventors: Sang-hun Lee, Changwon-si (KR); Se-chuel Park, Changwon-si (KR)

Correspondence Address: GARDNER CARTON & DOUGLAS LLP;ATTN: PATENT DOCKET DEPT., 191 N. WACKER DRIVE, SUITE 3700, CHICAGO, IL, 60606, US

(73) Assignee: Samsung Techwin Co., Ltd., Changwon-city (KR)

(21) Appl. No.: 11/202,052

(22) Filed: Aug. 11, 2005

(30) Foreign Application Priority Data
Apr. 26, 2005 (KR) 10-2005-0034551

(51) Int. Cl. H01L 23/495

(52) U.S. Cl. 257/666

(57) ABSTRACT

A lead frame for a semiconductor package and a manufacturing method thereof are provided. In the lead frame, a Ni plating layer made of Ni or a Ni alloy is plated on a base metallic layer. A Ni—Pd plating layer made of a Ni—Pd based alloy and having a Ni atomic concentration in a range of about 60% to about 95% is plated on the Ni plating layer, and a protective plating layer is plated on the Ni—Pd plating layer.

### CROSS-REFERENCE TO RELATED PATENT APPLICATION

This application claims the benefit of Korean Patent Application No. 10-2005-0034551, filed on Apr. 26, 2005, in the Korean Intellectual Property Office, the disclosure of which is incorporated herein in its entirety by reference.

### BACKGROUND OF THE INVENTION

1. Field of the Invention

The present invention relates to a lead frame for a semiconductor package and a method of manufacturing the same, and more particularly, to a lead frame which has a reduced galvanic potential difference between respective plating layers, and a method of manufacturing the same.

2. Description of the Related Art

FIG. 1 is a plan view of a conventional lead frame.

Referring to FIG. 1, a lead frame 100 includes a die pad 110 and a plurality of leads 120.

The die pad 110 supports a semiconductor chip (not shown), and is connected through a pad support 180 to a rail 170.

The plurality of leads 120 includes a plurality of inner leads 130 and a plurality of outer leads 140. The inner leads 130 are connected to the semiconductor chip and the outer leads 140 are connected to an external circuit (e.g., a printed circuit board).

A dam bar 160 is formed between the inner leads 130 and the outer leads 140 to maintain a constant gap between the leads 130 and 140. After a semiconductor package including a semiconductor chip and lead frame 100 is completely assembled, the rail 170 and the dam bar 160 are removed.

The lead frame 100 is assembled with the semiconductor chip, for example, a memory device, to provide a semiconductor package. A semiconductor assembly process includes steps of die attachment, wire bonding, and molding. The die attachment is a process of attaching a semiconductor chip (die) to a die pad of a lead frame. The wire bonding is a process of connecting a pin/connector/port of the semiconductor chip to an inner lead of the lead frame by a metal (e.g., gold) wire. The molding is a process of sealing the chip, wire and the inner lead of the lead frame by encapsulating, coating or otherwise covering the foregoing with an insulator such as thermosetting resin.

In order to enhance an adhesive strength between the semiconductor chip and the lead frame die pad during the die attachment process and a bonding property between a wire, the lead frame and the semiconductor chip during the wire bonding process, a metallic material is coated on the die pad 110 and the leads 130, 140. In order to enhance a solder wettability during a process of installing the outer lead 140 at the external circuit after the molding, Sn—Pb solder plating is performed on a specific portion of the outer lead 140.

However, the process of plating the Sn—Pb solder is complex and a Pb plating solution may cause an environmental problem. Moreover, there frequently occurs a case where the Pb plating solution infiltrates into a gap between a surface of a lead frame 100 and an epoxy molding during the Sn—Pb solder plating and thus a non-uniformity in a plating layer and a defect in the semiconductor chip are induced. Thus, an additional process for making the plating layer uniform is required.

Recently, a pre-plated frame (PPF) has been proposed for solving the above-mentioned problems. In this case, a material having an excellent wettability is pre-plated on a base metallic material of the lead frame prior to performing a semiconductor package process so as to omit a Pb plating process during a semiconductor post-process. A lead frame obtained by the pre-plating makes it possible to simplify the semiconductor package process and to reduce environmental pollution that may be caused by the Pb plating during a semiconductor package process.

FIG. 2 is a diagrammatic sectional view of a lead (e.g., FIG. 1 lead 120) of a lead frame manufactured through the conventional PPF technology.

Referring to FIG. 2, a Nickel (Ni) plating layer 122 is formed on a base metallic layer 121 that is made of a metal such as copper (Cu) or Iron (Fe), and a Palladium (Pd) plating layer 123 is formed on the Ni plating layer 122. That is, Nickel and Palladium are sequentially plated on the base metallic layer 121.

The Ni plating layer 122 prevent Copper or Iron of the base metallic layer 121 from diffusing into a surface of the lead frame 100 and thus generating an oxide or a sulfide. The Pd plating layer 123 has an excellent solder wettability and protects a surface of the Ni plating layer 122.

However, although a pre-process is performed prior to a plating process during the manufacture of the lead 120, a defective portion may exist in a surface of the base metallic layer 121. In this case, since Ni plating progresses at the defective portion more rapidly than other peripheral portions due to a high surface energy of the defective portion, the cohesion of the Ni plating layer 122 with peripheral portions is degraded and a plating surface becomes very rough.

Specifically, when the Pd plating layer 123 is formed, a large amount of hydrogen is adhered to during the Pd plating because of the small electrode potential difference between palladium and hydrogen. The adhered hydrogen increases an internal stress of the Pd plating layer 123. Specifically, when the Pd plating layer 123 is plated (e.g., electroplated) on a surface of the Ni plating layer 122 that is exposed at the defective portion (e.g., FIG. 3 crack 120c), a large amount of hydrogen is doped in during the extraction of palladium because the extraction potential of palladium is equal to that of hydrogen. The doped hydrogen causes an increase in the internal stress of the Pd plating layer 123. Accordingly, the density of the Pd plating layer 123 is degraded and thus a portion of the Pd plating layer 123 undesirably flakes off.

The degradation in the density of the Pd plating layer 123 causes the oxidation of the Ni plating layer 122 thereunder, resulting in degradation of the lead frame's wire bonding characteristic and solder wettability. Moreover, a thermal hysteresis causes the oxidation of the Pd plating layer 123, resulting in degradation of the excellent solder wettability of original palladium.

FIG. 3 is a diagrammatic view of another conventional lead frame for a semiconductor package, which is disclosed in U.S. Pat. No. 4,529,667.

Referring to FIG. 3, a lead frame is constructed with a protective plating layer 124 that is formed on a Pd plating layer 123 so as to solve the above-mentioned oxidation and degradation problems.

As illustrated in FIG. 3, plating layers are formed on at least one surface of a lead frame including a base metallic layer 121 that is made of Cu, a Cu alloy, or an Fe—Ni alloy. The plating layers include a Ni plating layer 122 made of Ni or a Ni alloy, a Pd plating layer 123 made of Pd or a Pd alloy and formed on the Ni plating layer 122, and a protective plating layer 124 made of Ag or an Ag alloy and formed on the Pd plating layer 123.

The high anti-oxidation ability of the Ag in the protective plating layer 124 effectively prevents the oxidation of the Pd plating layer 123 to improve the solder wettability thereof. However, this structure is effective only when a surface of a pre-plated lead frame is not physically damaged by the external environment.

As shown in FIG. 3, a crack 120c may occur in a surface plating structure resulting from the semiconductor package assembly process. Such a crack 120c causes a plating layer to flake off. Accordingly, portions of the Ni plating layer 122 and the Pd plating layer 123 are exposed to the environment. Consequently, a galvanic coupling due to a galvanic potential difference is induced and a corrosion reaction is accelerated.

In this case, when the base metallic layer 121 is made of alloy42, the corrosion reaction becomes more serious. As known in the art, alloy42 is made of Ni 42%, Fe 58%, and a small amount of other elements and is widely used as the material of the lead frame. However, since there is a great galvanic potential difference between the Fe or Ni constituent of the alloy42 and a Pd constituent of the Pd plating layer 123 or an Ag constituent the protective layer 124, a galvanic coupling develops and thus a very intense corrosion reaction is generated. This phenomenon also occurs when the protective plating layer 124 is made of Pt, Au, or the like.

As known, cracks and defects easily occur during the manufacture of the lead frame as shown in FIG. 3. These cracks and defects cause the protective plating layer 124 to flake off and accordingly the Pd plating layer 123 and the Ni plating layer 122 are exposed to oxygen in the atmosphere. Thus, a corrosion reaction due to the galvanic coupling is further accelerated at an exposed portion (e.g., crack 120c).

### SUMMARY OF THE INVENTION

The present invention provides a lead frame for a semiconductor package, which has a reduced galvanic potential difference between respective plating layers, and a method of manufacturing the same.

The present invention also provides a lead frame for a semiconductor package, which exhibits an excellent solder wettability and an excellent wire bonding property, and a method of manufacturing the same.

According to an aspect of the present invention, there is provided a lead frame for a semiconductor package, including: a base metallic layer; a Ni plating layer made of Ni or a Ni alloy plated on the base metallic layer; a Ni—Pd plating layer made of a Ni—Pd based alloy plated on the Ni plating layer; and a protective plating layer plated on the Ni—Pd plating layer.

The Ni—Pd plating layer may have a Ni atomic concentration in a range of about 60% to about 95%.

The Ni—Pd plating layer may have a thickness in a range of about 0.2 micro inches to about 4.0 micro inches.

The protective plating layer may be made of Au or an Au based alloy.

The lead frame may further include an Au—Pd plating layer made of an Au—Pd alloy and interposed between the Ni—Pd plating layer and the protective plating layer.

The Ni plating layer and the Ni—Pd layer constitute an intermediate plating layer and at least two intermediate plating layers may be stacked between the base metallic layer and the protective plating layer.

The base metallic layer may be made of alloy42.

According to another aspect of the present invention, there is provided a method of manufacturing a lead frame for a semiconductor package, the method including: providing a base metallic layer; plating a Ni plating layer made of Ni or a Ni alloy on the base metallic layer; plating a Ni—Pd plating layer made of a Ni—Pd based alloy with a Ni atomic concentration in a range of about 60% to about 95% on the Ni plating layer; and plating a protective plating layer on the Ni—Pd plating layer.

The Ni plating layer may have a thickness in a range of about 30 micro inches to about 100 micro inches, the Ni—Pd plating layer may have a thickness in a range of about 0.2 micro inches to about 4.0 micro inches, and the protective plating layer may be made of Au or an Au based alloy and has a thickness in a range of about 0.4 micro inches to about 1.5 micro inches.

The method may further include plating an Au—Pd plating layer of an Au—Pd alloy between the plating of the Ni—Pd plating layer and the forming of the protective plating layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view of a conventional lead frame for a semiconductor package;

FIG. 2 is a diagrammatic sectional view of a conventional lead frame.

FIG. 3 is a diagrammatic sectional view of another conventional lead frame for a semiconductor package;

FIG. 4 illustrates a perspective view of a semiconductor package according to an embodiment of the present invention and an enlarged diagrammatic sectional view of portion A of the package;

FIG. 5 is a diagrammatic sectional view illustrating a modification of the portion A in FIG. 4;

FIG. 6 is a diagrammatic sectional view illustrating another modification of the portion A in FIG. 4;

FIG. 7 is a flowchart illustrating a method of manufacturing the lead frame shown in FIG. 4;

FIG. 8A is a diagrammatic sectional view illustrating a result of a process of providing a base metallic layer so as to manufacture a lead frame according to an embodiment of the present invention;

FIG. 8B is a diagrammatic sectional view illustrating a result of a process of plating a Ni plating layer on the base metallic layer shown in FIG. 8A;

FIG. 8C is a diagrammatic sectional view illustrating a result of a process of plating a Ni—Pd plating layer on the Ni plating layer shown in FIG. 8B;

FIG. 8D is a diagrammatic sectional view illustrating a result of a process of plating a protective plating layer on the Ni—Pd plating layer shown in FIG. 8C;

FIG. 9A is an illustration of a convention lead frame, showing results of performing a salt water spray test thereon;

FIG. 9B is an illustration of a lead frame that is manufactured to have a Ni—Pd plating layer containing 95% nickel according to the present invention, showing results of performing a salt water spray test thereon;

FIG. 9C is an illustration of a lead frame that is manufactured to have a Ni—Pd plating layer containing 75% nickel according to the present invention, showing results of performing a salt water spray test thereon; and

FIG. 9D is an illustration of a lead frame that is manufactured to have a Ni—Pd plating layer containing 65% nickel according to the present invention, showing results of performing a salt water spray test thereon.

### DETAILED DESCRIPTION OF THE EMBODIMENTS

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

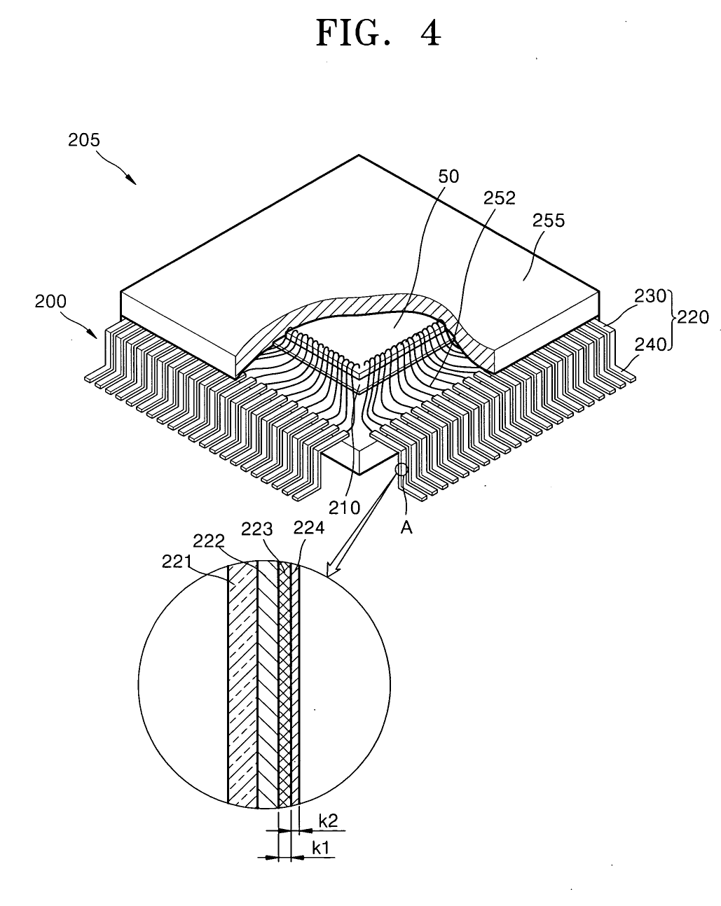

FIG. 4 illustrates a semiconductor package including a lead frame according to an embodiment of the present invention.

Referring to FIG. 4, a semiconductor package 205 has a structure in which a plurality of leads 220 of a lead frame 200 is electrically connected to a semiconductor chip 50.

As shown, the semiconductor chip 50 is seated on a die pad 210 so that a plurality of inner leads 230 and the semiconductor chip 50 are connected by a plurality of wires 252 through a wire bonding process, and a plurality of outer leads 240 is electrically connected to an external circuit (not shown). The semiconductor chip 50, wires 252 and the inner leads 230 are then protected by a molded resin 255 to constitute the semiconductor package 205.

As shown in the detail view of FIG. 4, the lead frame 200 includes a base metallic layer 221, a Ni plating layer 222, a Ni—Pd plating layer 223, and a protective plating layer 224. The base metallic layer 221 is a bare frame of the lead frame 200 and is made of metal formed mainly of Ni and Fe (e.g., alloy42) or Cu. In this case, the base metallic layer 221 is alloy42.

The Ni plating layer 222 is formed on the base metallic layer 221. The Ni plating layer 222 is made of Ni or a Ni alloy to prevent the metal of the base metallic layer 221 from spreading over a surface of the lead frame.

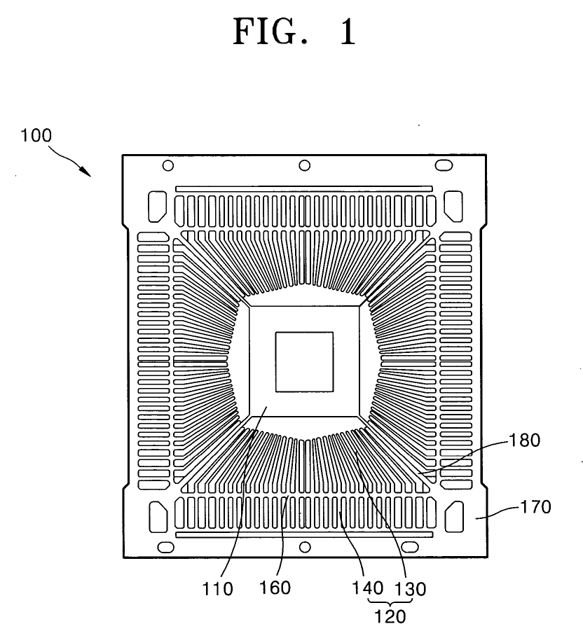

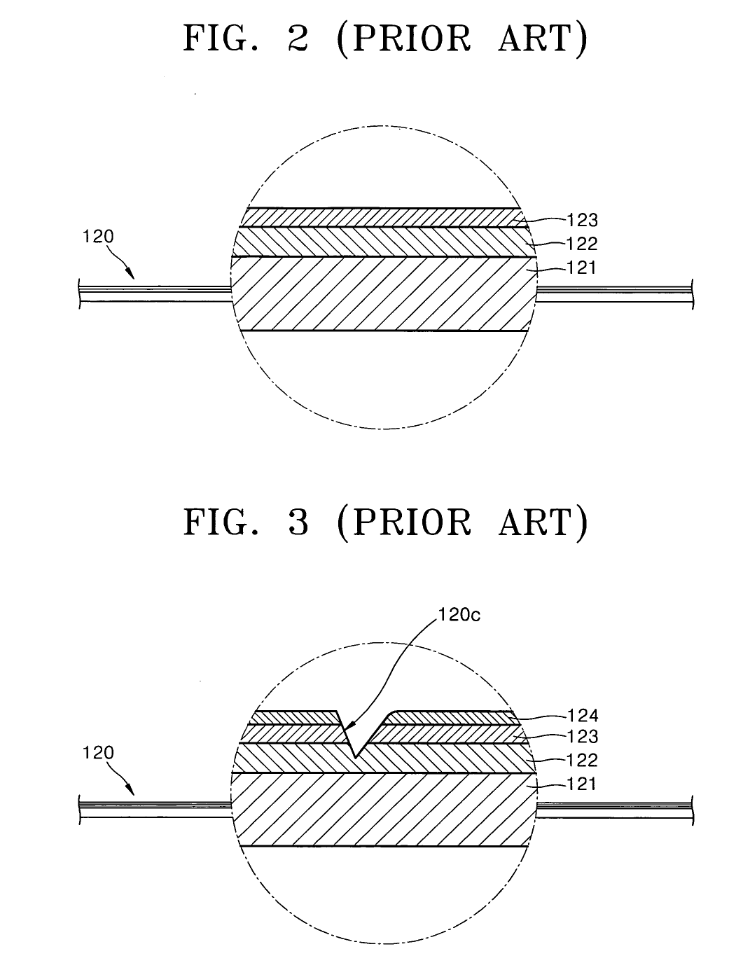

The Ni—Pd plating layer 223 is stacked on the Ni plating layer 222. The Ni—Pd layer 223 includes Pd and Ni. Unlike the conventional lead frame 100 (FIG. 1) that is formed to include the Ni plating layer 122 and the Pd plating layer 123 that are separate and have different galvanic potential differences, the Ni—Pd plating layer 223 includes Ni and Pd of constant atomic concentration. Accordingly, no galvanic potential difference occurs between the Ni plating layer 222 and the Ni—Pd plating layer 223. Consequently, a corrosion reaction due to a galvanic potential difference is prevented.

In this case, the Ni—Pd plating layer 223 preferably has a Ni atomic concentration in the range of about 60% to about 95%. This is because the Ni—Pd plating layer 223 having a Ni atomic concentration larger than 95% was determined experimentally to have a poor solder wettability and poor wire bonding property. Further, it was determined experimentally that the Ni—Pd plating layer 223 having a Ni atomic concentration smaller than 60% causes a galvanic potential difference between the Ni plating layer 222 and the Ni—Pd plating layer 223.

The protective plating layer 224 is formed on the Ni—Pd plating layer 223 to prevent the oxidation of the Ni—Pd plating layer 223. The protective plating layer 224 is preferably made of Au or an Au based alloy. The Au based alloy is an alloy having a similar characteristic as Au. The Au based alloy may include at least one element that is selected from the group consisting of Ag, Co, Ti, Pt and Pd.

In this case, the Ni—Pd plating layer 223 may be formed to have a thickness K1 of 0.2 micro inches to 4.0 micro inches, and the protective plating layer 224 may be formed to have a thickness K2 of 0.4 micro inches to 1.5 micro inches.

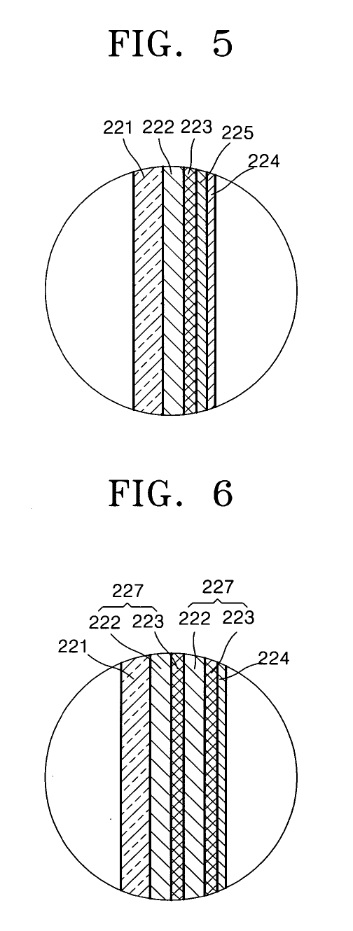

FIG. 5 is a diagrammatic sectional view illustrating a modification of the portion A in FIG. 4.

Referring to FIG. 5, an Au—Pd plating layer 225 may be formed between the Ni—Pd plating layer 223 and the protective plating layer 224. The Au—Pd plating layer 225 is made of an Au—Pd alloy to reduce a galvanic potential difference between the protective plating layer 224 and Pd that may be exposed on an upper surface of the Ni—Pd plating layer 223.

FIG. 6 is a diagrammatic sectional view illustrating another modification of the portion A in FIG. 4.

Referring to FIG. 6, the Ni plating layer 222 and the Ni—Pd plating layer 223 together form an intermediate plating layer 227. In this case, at least two intermediate plating layers 227 may be stacked between the base metallic layer 221 and the protective plating layer 224. This structure in which the least two intermediate plating layer 227 are stacked can further reduce a galvanic potential difference between the plating layers of the lead frame than a structure in which one intermediate plating layer 227 is stacked.

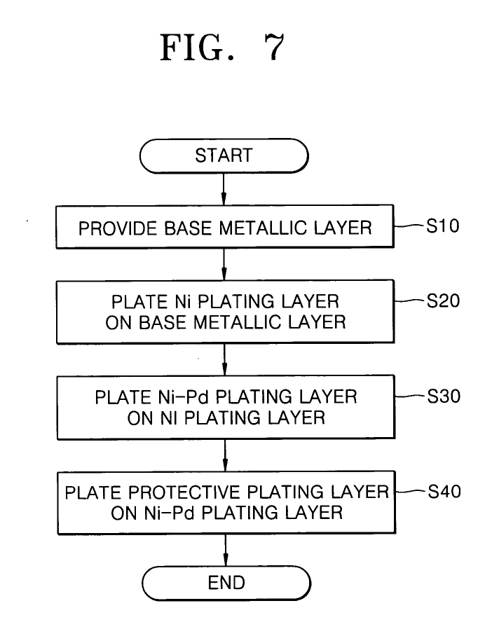

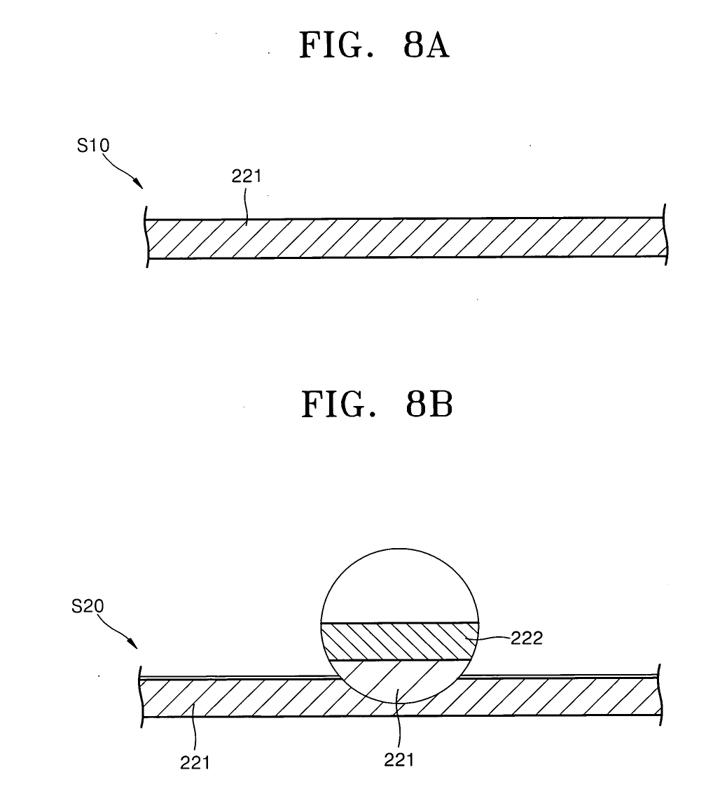

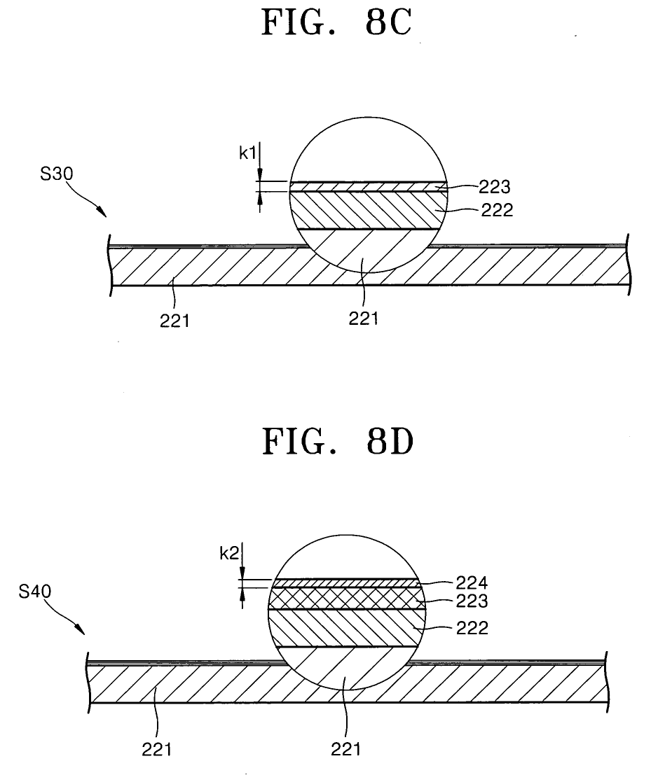

FIG. 7 is a flowchart illustrating a method of manufacturing the lead frame shown in FIG. 4. FIGS. 8A through 8D are diagrammatic sectional views illustrating respective results of the processes of a lead frame manufacturing method of FIG. 7. Here, a process of forming a plating layer on the base metallic layer, that is, the main material of the lead frame, is performed prior to a semiconductor package process of packaging the semiconductor chip and the lead frame. With reference to FIGS. 8A through 8D together with FIGS. 4 and 7, the structure of the lead frame 200 will be described in more detail and then the lead frame manufacturing method will also be described.

Referring to FIG. 8A, a base metallic layer 221 that is a bare frame of the lead frame is first provided in Operation S10 (FIG. 7). The base metallic layer 221 is made of metal material such as Cu or alloy42.

Referring to FIG. 8B, a Ni plating layer 222 is formed by plating Ni or a Ni alloy on the base metallic layer 221 through a chemical plating method or an electroplating method in Operation S20 (FIG. 7). The Ni plating layer 222 prevents the constituent materials of the base metallic layer 221 (such as Cu, Ni, Fe, and so on) from spreading into the surface of the lead frame 200.

Referring to FIG. 8C, a Ni—Pd plating layer 223 of a Ni—Pa based alloy is plated on the Ni plating layer 222 in Operation S30 (FIG. 7).

Pa (palladium) is known in the art as having both of excellent solder wettability and an excellent wire bonding property. Thus, Pd facilitates soldering and simultaneously protects the surface of the Ni plating layer 222 of the lead. However, there exists a great galvanic potential difference between Pd and the Ni or the Ni alloy constituting the Ni plating layer 222. Specifically, when the Ni plating layer 222 and Pd are exposed to the ambient atmosphere, the great galvanic potential difference causes a galvanic coupling between the Ni plating layer 222 and Pa, thereby accelerating the corrosion of the lead frame 200. In addition, the extraction potential of Pd is similar to that of hydrogen. Accordingly, when a plating layer of Pd or a Pd alloy is electrically plated on the Ni plating layer 222, a large amount of hydrogen is doped in during the extraction of Palladium. The doped hydrogen increases the internal stress of the Pd plating layer and accelerates the defects thereof, resulting in the acceleration of the corrosion of the lead frame 200.

Accordingly, the Ni—Pd plating layer 223, which is made of a Ni—Pd based alloy, is formed on the Ni plating layer 222 so as to solve the above-mentioned problems. Consequently, a galvanic potential difference between the Ni plating layer 222 and subsequent plating layers thereon is reduced and accordingly the solder wettability and wire bonding property of a lead is improved. Also, the hydrogen content of the Ni—Pd plating layer 223 is reduced with a reduction in the Pd atomic concentration thereof. Accordingly, the internal stress of the plating layer is reduced and consequently the corrosion of the lead frame 200 is reduced.

In this case, the Ni—Pd plating layer 223 preferably has a Ni atomic concentration in the range of about 60% to about 95%. That is, the Ni—Pd plating layer 223 cannot have a sufficient wire bonding property when the Ni atomic concentration is larger than 95%, and a great galvanic potential difference occurs between the Ni plating layer 222 and the lower surface of the Ni—Pd plating layer 223 facing the Ni plating layer 222 when the Ni atomic concentration is smaller than 60%. Accordingly, the galvanic potential difference can be reduced by increasing the Ni atomic concentration of the Ni—Pd plating layer 223 and reducing the Pd atomic concentration thereof.

The Ni—Pd plating layer 223 preferably has a thickness K1 in the range of about 0.2 micro inches to 4.0 micro inches. This is because the Ni—Pd plating layer 223 cannot sufficiently protect the Ni plating layer 222, cannot have a sufficient wire bonding property when the thickness K1 is smaller than 0.2 micro inches. Further, cost of the Ni—Pd plating layer 223 outweighs a benefit thereof when the thickness K1 is greater than 4.0 micro inches.

Referring to FIG. 8D, after the Ni—Pd plating layer 223 is formed, a protective plating layer 224 is formed on the Ni—Pd plating layer 223 in Operation S40. Since the Ni—Pd plating layer 223 has a larger content of Ni than Pd, a corrosion resistance is improved while a wire bonding property is degraded. The protective plating layer 224 improves the solder wettability. Herein, the protective plating layer 224 is a precious metal is because the precious metal has a high oxidation resistance. That is, the oxidation of the Ni—Pd plating layer 223 is prevented by plating the precious metal on the Ni—Pd plating layer 233.

The protective plating layer 224 may be an Au or an Au based alloy. The Au based alloy may include Au and at least one element selected from the group consisting of Ag, Co, Ti, Pt and Pd. In this case, the protective plating layer 224 is formed to have a thickness K2 in the range of about 0.4 micro inches to 1.5 micro inches.

Although not shown in the figures, a process of forming an Au—Pd plating layer may be further included between the process of forming the Ni—Pd plating layer 223 and the process of forming the protective plating layer 224. The Au—Pd plating layer is made of an Au—Pa alloy to reduce a galvanic potential difference between the protective plating layer 224 and Pd metal that is exposed on an upper surface of the Ni—Pd plating layer 223.

Also, at least two intermediate plating layers 227, each comprising the Ni plating layer 222 and the Ni—Pd plating layer 223, may be stacked between the base metallic layer 221 and the protective plating layer 224 as illustrated in FIG. 6. This structure in which at least two intermediate plating layer 227 are stacked can further reduce a galvanic potential difference between the plating layers of the lead frame than a structure in which one intermediate plating layer 227 is stacked.

The advantageous effects of the lead frame 200 can be seen from the following explanatory experiment:

Samples

In this experiment, three 66TSOP2 alloy42 pre-plated lead frames are used. The three 66TSOP2 alloy42 pre-plated lead frames are manufactured by: forming a Ni plating layer 222 on a base metallic layer 221 made of alloy42 to have a thickness in the range of about 30 micro inches to 100 micro inches; forming a Ni—Pd plating layer 223 on the Ni plating layer 222 to have a thickness in the range of about 0.2 micro inches to 4.0 micro inches; and forming a protective plating layer 224 of Au or an Au alloy to have a thickness of 0.4 micro inches to 1.5 micro inches. The Pd atomic concentration of the Ni—Pd plating layer 223 for a first sample pre-plated lead frame is 5%, the Pd atomic concentration of the Ni—Pd plating layer 223 for a second sample pre-plated lead frame is 25%, and the Pd atomic concentration of the Ni—Pd plating layer 223 for a third sample pre-plated lead frame is 35%.

For comparison with the three foregoing-described samples, a conventional lead frame is manufactured by: forming a Ni plating layer on a base metallic layer of alloy42 material to have a thickness in the range of about 30 micro inches to 100 micro inches; forming a Pd plating layer on the Ni plating layer to have a thickness in the range of about 0.2 micro inches to 4.0 micro inches; and forming a protective plating layer of an Au alloy to have a thickness in the range of about 0.4 micro inches to 1.5 micro inches.

Salt Water Spray Test

Corrosion resistance of the foregoing-described three samples was evaluated by performing a salt water spray test. NaCI dissolved in water and having an atomic concentration of 5% was sprayed on the samples at 150 g/m² for a duration of 24 hours at a chamber temperature of 35° C.

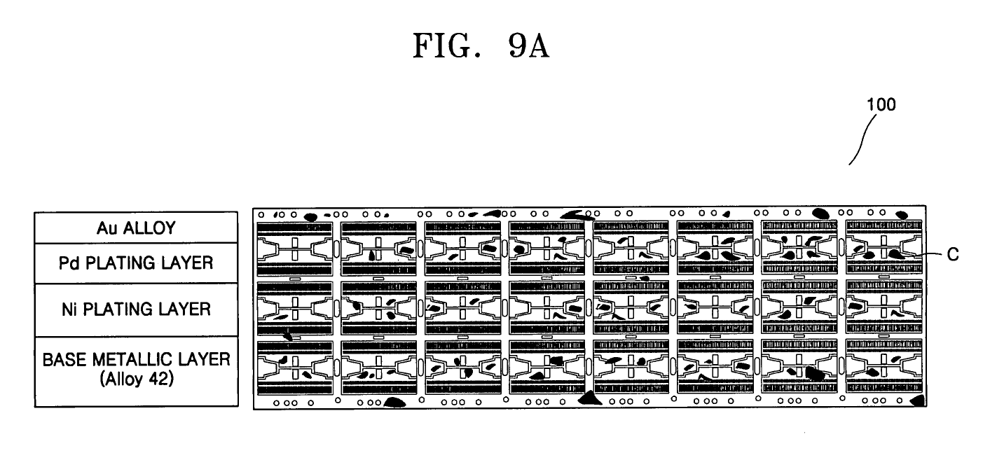

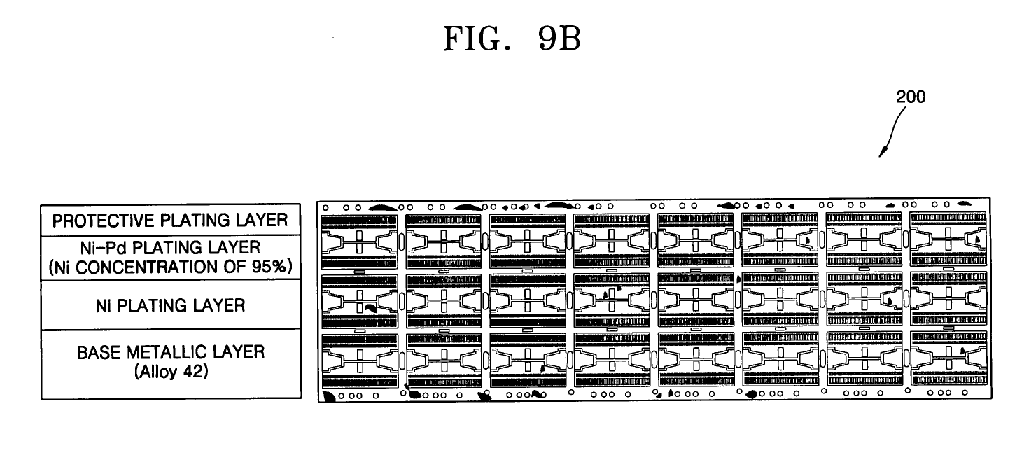

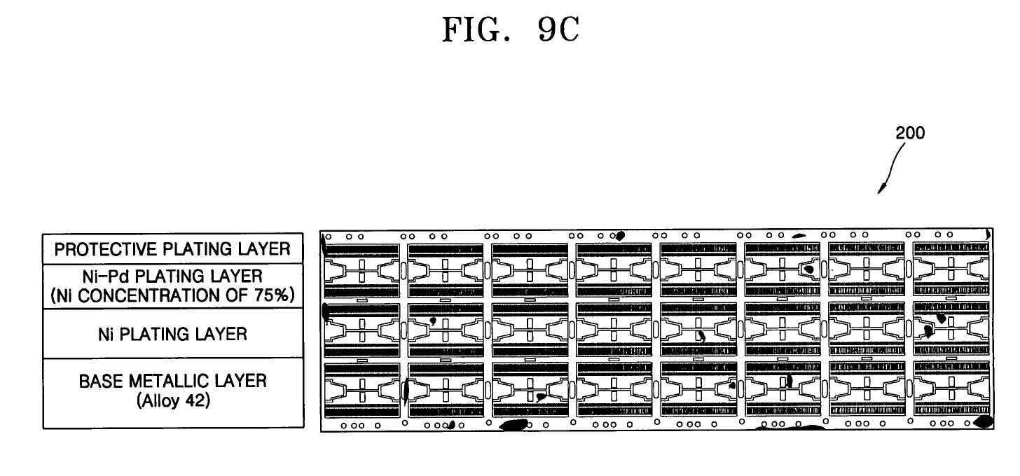

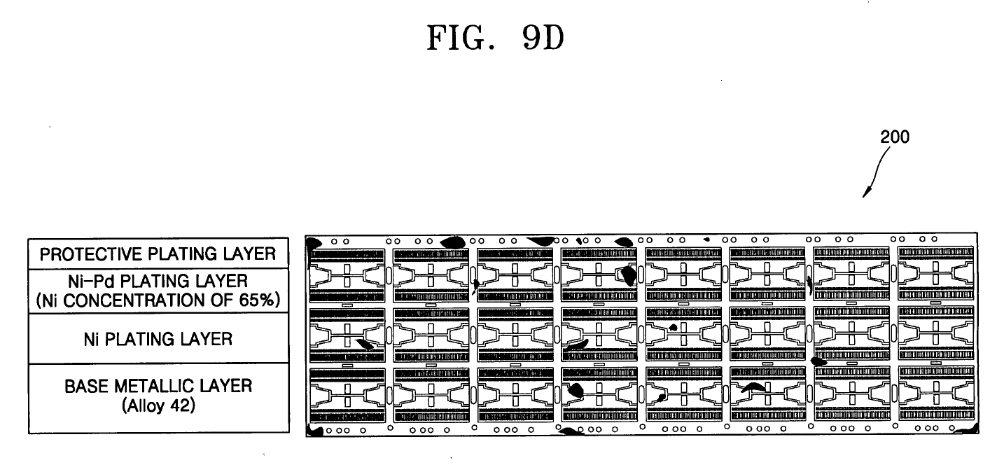

FIG. 9A illustrates the conventional lead frame after completion of the salt water spray test. It can be seen from FIG. 9A that a large portion, indicated by reference letter C, of the lead frame 100 has been corroded.

FIGS. 9B through 9D illustrate the states of the three sample lead frames that include the Ni—Pd plating layers having Pd atomic concentrations of 5%, 25%, and 35%, respectively, after completion of the salt water spray test. It can be seen from FIGS. 9B through 9D that the lead frames have minimal corrosion.

As can be appreciated from FIGS. 9A-9D, the galvanic potential difference can be reduced by forming the Ni—Pd plating layer on the Ni plating layer and accordingly the corrosion of the lead frame 200 can be prevented or minimized.

As described above, the galvanic potential difference between the Ni plating layer and the plating layer plated thereon can be reduced by forming the Ni—Pd layer prior to the forming of the protective plating layer. Also, a reduction of the density of the plating layer due to doped hydrogen and accordingly flaking off a portion of the plating layer can be prevented.

Consequently, the corrosion of the lead frame can be prevented and simultaneously the wire bonding property and solder wettability of the lead frame can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A lead frame for a semiconductor package, comprising:
a base metallic layer;
a Ni plating layer on the base metallic layer;
a Ni—Pd plating layer on the Ni plating layer, the Ni—Pd plating layer comprising Ni in an atomic concentration a range of about 60% to about 95%; and
a protective plating layer on the Ni—Pd plating layer.

2. The lead frame of claim 1 wherein the Ni—Pd plating layer has a thickness in a range of about 0.2 micro inches to about 4.0 micro inches.

3. The lead frame of claim 1 wherein the protective plating layer comprises a precious metal having a thickness in a range of about 0.4 micro inches to about 1.5 micro inches.

4. The lead frame of claim 3 wherein the protective plating layer further comprises at least one element selected from the group consisting of Ag, Co, Ti, Pt and Pd.

5. The lead frame of claim 3 wherein the precious metal is Au or an Au based alloy.

6. The lead frame of claim 1 further comprising an Au—Pd plating layer, the Au—Pd plating layer being interposed between the Ni—Pd plating layer and the protective plating layer to reduce a galvanic potential difference therebetween.

7. The lead frame of claim 1 further comprising:
a second Ni plating layer; and
a second Ni—Pd plating layer on the second Ni plating layer, wherein the second Ni plating layer and the second Ni—Pd plating layer are interposed between the Ni—Pd plating layer and the protective plating layer.

8. The lead frame of claim 7 wherein the second Ni—Pd plating layer is substantially similar to the Ni—Pd plating layer.

9. The lead frame of claim 1 wherein the base metallic layer is one of alloy42 and Cu.

10. A method of manufacturing a lead frame for a semiconductor package, the method comprising:
forming a Ni plating layer on a base metallic layer comprising one of alloy42 and Cu;
forming a Ni—Pd plating layer on the Ni plating layer, the Ni—Pd plating layer having a Ni atomic concentration in a range of about 60% to about 95%; and
forming a precious metal protective plating layer on the Ni—Pd plating layer.

11. The method of claim 10 further comprising, after the step of forming a Ni—Pd plating layer, forming a Au—Pd plating layer on the Ni—Pd plating layer.

12. The method of claim 10 further comprising, after the step of forming a Ni—Pd plating layer:
forming a second Ni plating layer on the Ni—Pd plating layer; and
forming a second Ni—Pd plating layer on the second Ni plating layer.

13. The method of claim 12 further comprising, after the step of forming a second Ni—Pd plating layer, forming a Au—Pd plating layer on the second Ni—Pd plating layer.

14. A lead frame for a semiconductor package, the lead frame made by the process of:
providing an alloy42 layer;
plating a Ni layer on the alloy42 layer, the Ni layer having a thickness in a range of about 30 micro inches to about 100 micro inches;
plating a Ni—Pd layer on the Ni layer, the Ni—Pd layer having a Ni atomic concentration in a range of about 60% to about 95% and having a thickness in a range of about 0.2 micro inches to about 4.0 micro inches; and
plating an Au layer on the Ni—Pd layer, the Au layer having a thickness in a range of about 0.4 micro inches to about 1.5 micro inches.

15. The lead frame of claim 14 wherein the process further comprises, after the step of plating a Ni—Pd layer, plating a Au—Pd layer on the Ni—Pd layer.

16. The lead frame of claim 14 wherein the process further comprises, after the step of plating a Ni—Pd layer:
plating a second Ni layer on the Ni—Pd layer, the second Ni layer having a thickness in a range of about 30 micro inches to about 100 micro inches; and
forming a second Ni—Pd layer on the second Ni layer, the second Ni—Pd layer having a Ni atomic concentration in a range of about 60% to about 95% and having a thickness in a range of about 0.2 micro inches to about 4.0 micro inches.

17. The method of claim 16 further comprising, after the step of forming a second Ni—Pd plating layer, forming a Au—Pd plating layer on the second Ni—Pd plating layer.
